(19) United States
(12) Patent Application Publication
(10) Pub. No.: US 2025/0031331 A1
(43) Pub. Date: Jan. 23, 2025

(54) FLEXIBLE GLASS AND ELECTRONIC APPARATUS COMPRISING SAME

(71) Applicant: Samsung Electronics Co., Ltd., Suwon-si (KR)

(72) Inventor: Jaehyun BAE, Suwon-si (KR)

(73) Assignee: Samsung Electronics Co., Ltd., Suwon-si (KR)

(21) Appl. No.: 18/909,560

(22) Filed: Oct. 8, 2024

Related U.S. Application Data
(63) Continuation of application No. PCT/KR2023/002713, filed on Feb. 27, 2023.

(30) Foreign Application Priority Data
Apr. 28, 2022 (KR) 10-2022-0052516
Jun. 2, 2022 (KR) 10-2022-0067618

(51) Int. Cl. H05K 5/03; H05K 5/02

(52) U.S. Cl. CPC H05K 5/03; H05K 5/0226

(57) ABSTRACT

A flexible glass including: a flexible area configured to move between a planar shape and a curved shape with respect to at least one folding axis extending along a first direction; a planar area provided on at least one side of the flexible area; and a plurality of first holes provided in at least a portion of the flexible area, where the plurality of first holes extend along the first direction and are provided along a second direction intersecting the first direction in an arrangement area of the flexible area, and a first width of the arrangement area along the second direction of at least one edge of the flexible area intersecting the at least one folding axis is greater than a second width of the arrangement area at a center between edges of the flexible area.

### CROSS-REFERENCE TO RELATED APPLICATION(S)

This application is a continuation of International Application No. PCT/KR2023/002713, filed on Feb. 27, 2023, in the Korean Intellectual Property Receiving Office, which is based on and claims priority to Korean Patent Applications No. 10-2022-0052516, filed on Apr. 28, 2022 and No. 10-2022-0067618, filed on Jun. 2, 2022, in the Korean Intellectual Property Office, the disclosures of which are incorporated by reference herein in their entireties.

### BACKGROUND

### 1. Field

Embodiment(s) of the disclosure relate to an electronic device, for example, a flexible glass which is at least partially flexible and/or an electronic device including the same.

### 2. Description of Related Art

An electronic device may refer to a device that executes a specified function according to a loaded program, such as a home appliance, an electronic notebook, a portable multimedia player, a mobile communication terminal, a tablet PC, a video/audio device, a desktop/laptop computer, or a vehicle navigation device. For example, these electronic devices may output stored information as sound or an image. As the integration level of electronic devices increases and high-speed, large-capacity wireless communication becomes more common, a single electronic device such as a mobile communication terminal may recently be equipped with various functions. For example, an entertainment function such as games, a multimedia function such as music/video playback, a communication and security function for mobile banking, and a function such as schedule management or an electronic wallet in addition to a communication function are integrated into a single electronic device.

As the use of personal or portable communication devices such as smartphones becomes more common, user demands for portability and ease of use are increasing. For example, a touch screen display may provide a screen, for example, a virtual keypad which is an output device outputting visual information and substitutes for a mechanical input device (e.g., a button-type input device). Therefore, a portable communication device or electronic device may be miniaturized while providing the same or improved usability (e.g., a larger screen). On the other hand, the portability and ease of use of electronic devices is expected to be further enhanced along with the commercialization of flexible displays, for example, foldable or rollable displays. An electronic device including a flexible display may be carried with a plurality of different structures (e.g., housings) folded or rolled, and provide a large screen when unfolded, thereby improving portability and ease of use.

The above information is presented as background information only to assist with an understanding of the disclosure. No determination has been made, and no assertion is made, as to whether any of the above might be applicable as prior art with regard to the disclosure.

### SUMMARY

A display may include a window glass to protect a display panel (e.g., a light emitting layer, an electrode layer, and/or an encapsulation layer). For example, the window glass may protect the display panel from an external environment while transmitting light or a screen output from the display panel. For example, the window glass may suppress or prevent contamination of the display panel by a foreign material such as dust, and alleviate or prevent external pressure or impact on the display panel. However, in a flexible display that is foldable or rollable and/or an electronic device including the same, it may be difficult for the window glass to stably protect the display panel while having flexibility enough to allow deformation.

An embodiment of the disclosure is intended to address at least the above-mentioned problems and/or disadvantages and provide at least the advantages described later, and may provide a flexible glass deformable between a planar shape and a curved shape and/or an electronic device including the same.

An embodiment of the disclosure may provide a flexible glass for stably protecting a display panel, while having flexibility, and/or an electronic device including the same.

Additional aspects according to various embodiments will be set forth in the following detailed description, and will be apparent in part from the description or may be understood from an embodiment of a presented implementation.

According to an embodiment of the disclosure, a flexible glass may include a flexible area including a first side edge and a second side edge, and a lattice pattern area provided between the first side edge and the second side edge, the flexible area configured to be movable between a planar shape and a curved shape with respect to at least one folding axis extending along a first direction, and a planar area provided on at least one side of the flexible area. The lattice pattern area including a plurality of first holes filled with a material for compensating a refractive index deviation of transmitted light in the flexible area. A first width of the lattice pattern area corresponding to at least one of the first side edge or the second side edge of the flexible area intersecting the at least one folding axis is greater than a second width of the lattice pattern area at a center between the first side edge and the second side edge of the flexible area.

According to an embodiment of the disclosure, a flexible glass may include: a flexible area configured to move between a planar shape and a curved shape with respect to at least one folding axis extending along a first direction; a planar area provided on at least one side of the flexible area; and a plurality of first holes provided in at least a portion of the flexible area, where the plurality of first holes extend along the first direction and are provided along a second direction intersecting the first direction in an arrangement area of the flexible area, and a first width of the arrangement area along the second direction of at least one edge of the flexible area intersecting the at least one folding axis is greater than a second width of the arrangement area at a center between edges of the flexible area.

An edge of the arrangement area may include at least one of a straight section or a curved section.

A width of the plurality of first holes along the second direction may increase based on a distance to the at least one edge.

A spacing between two adjacent first holes among the plurality of first holes may decrease based on a distance to the at least one edge.

The flexible glass may further include a compensating material provided in the plurality of first holes, where the compensating material is configured to compensate for a refractive index deviation of transmitted light in the flexible area.

An edge of the arrangement area may include at least one of a straight section or a curved section.

A width of the plurality of first holes along the second direction may increase based on a distance to the at least one edge.

A spacing between two adjacent first holes among the plurality of first holes may decrease based on a distance to the at least one edge.

The flexible glass may further include a compensating material provided in the plurality of first holes, where the compensating material is configured to compensate for a refractive index deviation of transmitted light in the flexible area.

The compensating material may be further provided on at least one surface of the flexible glass.

The flexible glass may further include: a glass layer provided from the flexible area to the planar area; and a coating layer provided on at least one surface of the glass layer.

The plurality of first holes may be provided in the coating layer.

The plurality of first holes may be provided in the coating layer, where the glass layer includes a plurality of second holes corresponding to the plurality of first holes.

The flexible glass may further include a compensating material provided in at least some of the plurality of first holes or the plurality of second holes, where the compensating material is configured to compensate for a refractive index deviation of transmitted light in the flexible area.

The planar area may be provided on both sides of the flexible area, where the planar area on both sides are provided side by side, each on one side of the other, with the flexible area between the planar areas and at least partially facing each other as the flexible area is moved.

The flexible area may be provided side by side on one side of the planar area and configured to be moved to a position in which the flexible area at least partially faces the planar area at a specified spacing.

According to an aspect of the disclosure, an electronic device may include: a first housing; a second housing coupled to the first housing and configured to move with respect to the first housing; and a flexible display including a first display area provided on the first housing, and a folding area extending from the first display area and configured to be moved into a planar shape and a curved shape according to movement of the second housing, wherein the flexible display includes the flexible glass including: a flexible area configured to move between the planar shape and the curved shape with respect to at least one folding axis extending along a first direction; a planar area provided on at least one side of the flexible area; and a plurality of first holes provided in at least a portion of the flexible area, where the plurality of first holes extend along the first direction and are provided along a second direction intersecting the first direction in an arrangement area of the flexible area, and a first width of the arrangement area along the second direction of at least one edge of the flexible area intersecting the at least one folding axis is greater than a second width of the arrangement area at a center between edges of the flexible area, and where the flexible area of the flexible glass is provided in the folding area.

A hinge may provide the at least one folding axis, corresponding to the folding area, and pivotably connect the first housing and the second housing to each other, where the second housing is configured to move with respect to the at least one folding axis between a folded state in which the second housing faces the first housing and a flat state in which the second housing moves from the folded state by a specified angle.

The flexible display may further include a second display area extending from the folding area and disposed on the second housing, where in the folded state, the second display area is at least partially faces the first display area.

### BRIEF DESCRIPTION OF DRAWINGS

The above and other aspects, features and/or advantages of an embodiment of the disclosure will be more apparent from the following description taken in conjunction with the accompanying drawings, in which:

FIG. 1 is a diagram illustrating an electronic device in a flat state according to an embodiment of the disclosure;

FIG. 2 is a diagram illustrating an electronic device in a folded state according to an embodiment of the disclosure;

FIG. 3 is an exploded perspective view illustrating an electronic device according to an embodiment of the disclosure;

FIG. 4 is a plan view illustrating a flexible glass according to an embodiment of the disclosure;

FIG. 5 is a plan view illustrating a flexible glass according to an embodiment of the disclosure;

FIG. 6 is a plan view illustrating a flexible glass according to another embodiment of the disclosure;

FIG. 7 is a perspective view illustrating a flexible glass according to an embodiment of the disclosure;

FIG. 8 is a cross-sectional view illustrating the flexible glass taken along line S1 in FIG. 7 according to an embodiment of the disclosure;

FIG. 9 is a cross-sectional view illustrating the flexible glass taken along line S2 in FIG. 7 according to an embodiment of the disclosure;

FIG. 10 and FIG. 11 are cross-sectional views illustrating modified examples of the flexible glass of FIG. 7 according to one or more embodiments of the disclosure;

FIG. 12 is a perspective view illustrating a flexible glass according to an embodiment of the disclosure;

FIG. 13 is a cross-sectional view illustrating the flexible glass taken along line S1 in FIG. 12 according to an embodiment of the disclosure;

FIG. 14 is a cross-sectional view illustrating the flexible glass taken along line S2 in FIG. 12 according to one or more embodiments of the disclosure;

FIG. 15 and FIG. 16 are cross-sectional views illustrating modified examples of the flexible glass of FIG. 12 according to an embodiment of the disclosure;

FIG. 17 is a perspective view illustrating a flexible glass according to another embodiment of the disclosure;

FIG. 18 is a cross-sectional view illustrating the flexible glass taken along line S1 in FIG. 17 according to an embodiment of the disclosure;

FIG. 19 is a cross-sectional view illustrating the flexible glass taken along line S2 in FIG. 17 according to an embodiment of the disclosure;

FIG. 20 is a cross-sectional view illustrating a modified example of the flexible glass of FIG. 17 according to an embodiment of the disclosure;

FIG. 21 is a cross-sectional view illustrating a flexible glass according to another embodiment of the disclosure;

FIG. 22 is a cross-sectional view illustrating a modified example of the flexible glass of FIG. 21 according to an embodiment of the disclosure;

FIG. 23 and FIG. 24 are perspective views illustrating modified examples of a flexible glass according to an embodiment of the disclosure;

FIG. 25 is a diagram illustrating a process for fabricating a flexible glass according to an embodiment of the disclosure; and

FIG. 26 is a diagram illustrating another exemplary process for fabricating a flexible glass according to an embodiment of the disclosure.

Throughout the accompanying drawings, like reference numerals may be assigned to like parts, components and/or structures.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms. It is to be understood that singular forms include plural referents unless the context clearly dictates otherwise. The terms including technical or scientific terms used in the disclosure may have the same meanings as generally understood by those skilled in the art.

The terms and words used in the following description and claims are not limited to referential meanings and may be used to clearly and consistently describe various embodiments of the disclosure. Therefore, it is obvious to those skilled in the art that the following description of various implementations of the disclosure is provided for illustrative purposes and not for the purpose of limiting the scope of the disclosure and its equivalents.

Unless the context clearly dictates otherwise, the singular forms “a”, “an”, and “the” should be understood to include plural meanings. Accordingly, for example, “a surface of a component” may be understood to include one or more of the surfaces of the component.

An electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases. As used herein, such terms as “1^{st}” and “2^{nd}”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., a program) including one or more instructions that are stored in a storage medium (e.g., internal memory or external memory) that is readable by a machine (e.g., an electronic device). For example, a processor (e.g., a processor) of the machine (e.g., the electronic device) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

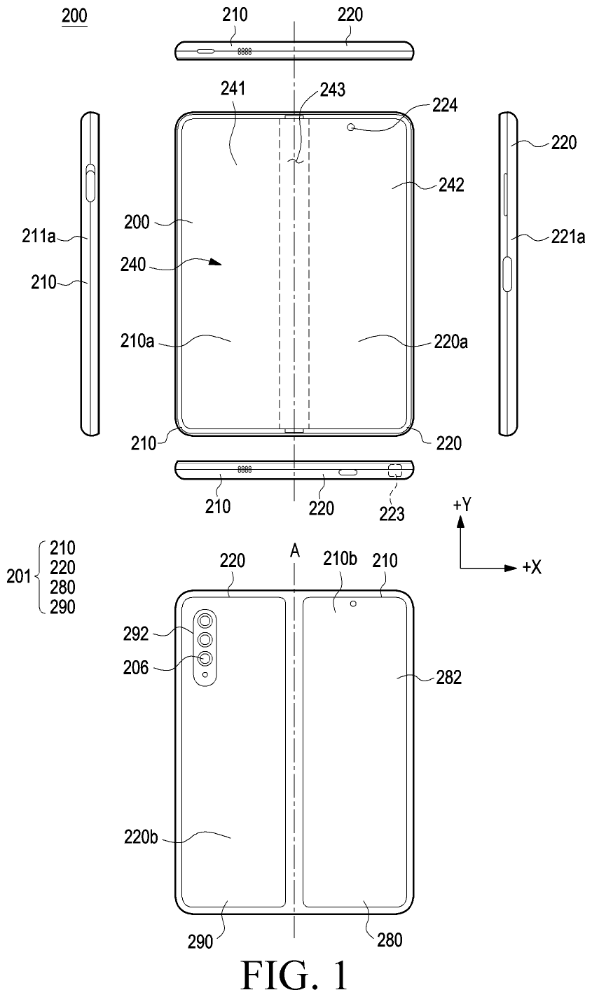

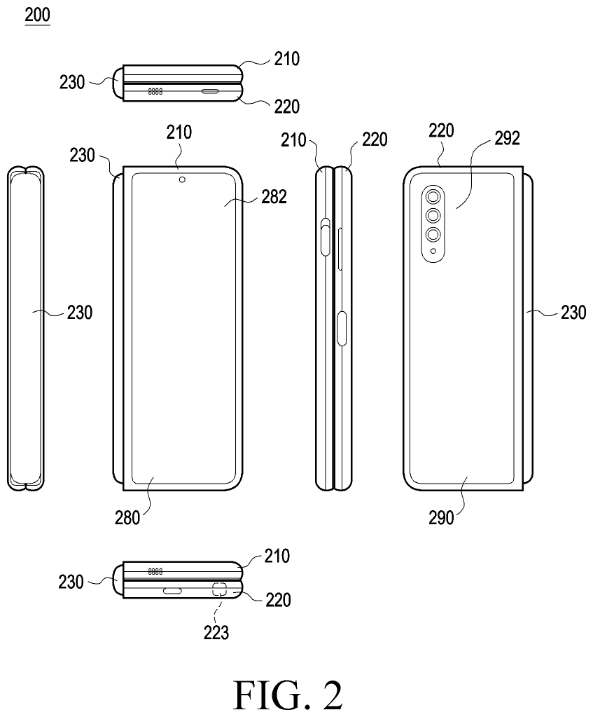

FIG. 1 is a diagram illustrating an electronic device in a flat state according to an embodiment of the disclosure. FIG. 2 is a diagram illustrating the electronic device in a folded state according to an embodiment of the disclosure.

Referring to FIGS. 1 and 2, in an embodiment, an electronic device 200 may include a housing 201, a hinge cover 230 that covers a foldable portion of the housing 201, and a flexible or foldable display 240 (hereinafter, shortly referred to as a “display” 240) disposed in a space formed by the housing 201. According to an embodiment, a surface on which the display 240 is disposed is defined as a front surface (e.g., a first front surface 210a and a second front surface 220a) of the electronic device 200. Further, a surface opposite to the front surface is defined as a rear surface (e.g., a first rear surface 210b and a second rear surface 220b) of the electronic device 200. Further, a surface surrounding a space between the front and rear surfaces is defined as a side surface (e.g., a first side surface 211a and a second side surface 221a) of the electronic device 200.

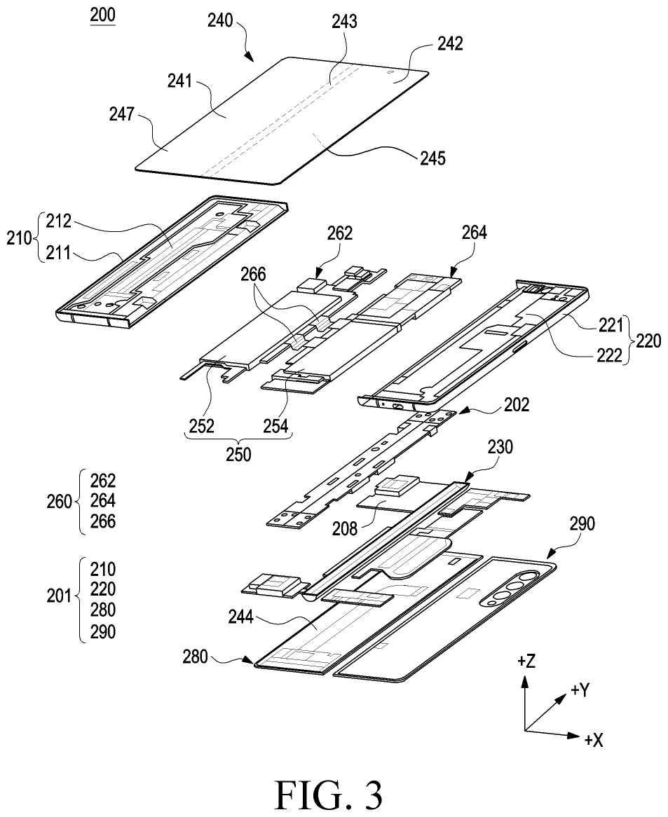

According to an embodiment, the housing 201 may include a first housing 210, a second housing 220 rotatably or pivotably coupled to the first housing 210, a first rear cover 280, a second rear cover 290, and a hinge module (e.g., a hinge module 202 in FIG. 3). The hinge module 202 may provide at least one folding axis A which is the center of rotation of the first housing 210 and/or the second housing 220. The housing 201 of the electronic device 200 is not limited to the shape and coupling illustrated in FIGS. 2 and 3, and may be implemented in other shapes or other combinations and/or coupling of components. For example, in an embodiment, the first housing 210 and the first rear cover 280 may be formed integrally, and the second housing 220 and the second rear cover 290 may be formed integrally. According to an embodiment, the first housing 210 may be connected to the hinge module (e.g., the hinge module 202 of FIG. 3) and include the first front surface 210a facing a first direction and the first rear surface 210b facing a second direction opposite to the first direction. The second housing 220 may be connected to the hinge module 202, include the second front surface 220a facing a third direction and the second rear surface 220b facing a fourth direction opposite to the third direction, and rotate with respect to the first housing 210 around the hinge module 202. Accordingly, the electronic device 200 may be changed to the folded state or the flat state. When the electronic device 200 is in the folded state, the first front surface 210a may face the second front surface 220a, and when the electronic device 200 is in the flat state, the third direction may be substantially parallel to the first direction. Unless otherwise stated, the directions will be described below based on the flat state of the electronic device 200.

According to an embodiment, the first housing 210 and the second housing 220 may be disposed on both sides of the folding axis A and have an overall symmetrical shape with respect to the folding axis A. As described later, an angle or distance between the first housing 210 and the second housing 220 may vary depending on whether the electronic device 200 is in the flat state, the folded state, or an intermediate state. According to an embodiment, although unlike the first housing 210, the second housing 220 further includes a sensor area 224 in which various sensors (e.g., a front camera) are disposed, the second housing 220 may have a symmetrical shape with the first housing 210 in the other area. According to an embodiment, the folding axis A may be a plurality of (e.g., two) parallel folding axes. In an embodiment of the disclosure, the folding axis A is provided along a longitudinal direction (Y-axis direction) of the electronic device 200, to which the direction of the folding axis A is not limited. For example, depending on an external design or a user's usage habits, the electronic device 200 may be understood as including the folding axis A extending along a width direction (e.g., X-axis direction).

According to an embodiment, the electronic device 200 may include a structure into which a digital pen may be inserted. For example, a hole 223 into which the digital pen may be inserted may be formed on a side surface of the first housing 210 or the second housing 220 of the electronic device 200.

According to an embodiment, at least a portion of the first housing 210 and the second housing 220 may be formed of a metallic material or non-metallic material having a selected level of rigidity to support the display 240. At least a portion formed of the metallic material may provide a ground plane of the electronic device 200 and be electrically connected to a ground conductor provided on a printed circuit board (PCB)(e.g., a board unit 260 in FIG. 3).

According to an embodiment, the sensor area 224 may be formed to have a predetermined area adjacent to a corner of the second housing 220. However, the arrangement, shape, and size of the sensor area 224 are not limited to the illustrated example. For example, in an embodiment, the sensor area 224 may be provided in another corner of the first housing 210, in any area between top and bottom corners of the second housing or in the first housing 210. According to an embodiment, components for performing various functions built in the electronic device 200 may be visually exposed from the front surface of the electronic device 200 through the sensor area 224 or through one or more openings provided in the sensor area 224. In an embodiment, the components may include various types of sensors. The sensors may include, for example, at least one of a front camera, a receiver, or a proximity sensor.

According to an embodiment, the first rear cover 280 may be disposed on one side of the folding axis A on the rear surface of the electronic device 200, and have, for example, a substantially rectangular periphery, which may be surrounded by the first housing 210. Similarly, the second rear cover 290 may be disposed on the other side of the folding axis A on the rear surface of the electronic device 200, and have its periphery surrounded by the second housing 220.

According to an embodiment, the first rear cover 280 and the second rear cover 290 may have a substantially symmetrical shape with respect to the folding axis A. However, the first rear cover 280 and the second rear cover 290 do not necessarily have a mutually symmetrical shape, and in an embodiment, the electronic device 200 may include the first rear cover 280 and the second rear cover 290 of various shapes.

According to an embodiment, the first rear cover 280, the second rear cover 290, the first housing 210, and the second housing 220 may form a space in which various components (e.g., a PCB or a battery) of the electronic device 200 may be disposed. According to an embodiment, one or more components may be disposed or visually exposed on the rear surface of the electronic device 200. For example, at least a portion of a sub-display (e.g., a sub-display 244 in FIG. 3) may be visually exposed through a first rear area 282 of the first rear cover 280. In an embodiment, one or more components or sensors may be visually exposed through a second rear area 292 of the second rear cover 290. In an embodiment, the sensors may include a proximity sensor and/or a camera module 206 (e.g., a rear camera).

According to an embodiment, the front camera exposed from the front surface of the electronic device 200 through one or more openings provided in the sensor area 224 or the camera module 206 visually exposed through the second rear area 292 of the second rear cover 290 may include one or more lenses, an image sensor, and/or an image signal processor. In an embodiment, two or more lenses (an infrared camera, a wide-angle lens, and a telephoto lens) and image sensors may be disposed on one surface of the electronic device 200.

Referring to FIG. 2, the hinge cover 230 may be configured to be disposed between the first housing 210 and the second housing 220 to cover an internal component (e.g., the hinge module 202 in FIG. 3). According to an embodiment, the hinge cover 230 may be covered by a portion of the first hosing 210 and the second housing 220 or exposed to the outside, depending on the state (e.g., unfolded state or folded state) of the electronic device 200. For example, in the flat state, the hinge cover 230 may be substantially covered by the first housing 210 and the second housing 220, and in the folded state, most of an outer surface of the hinge cover 230 may be exposed to the outside.

According to an embodiment, when the electronic device 200 is in the flat state as illustrated in FIG. 1, the hinge cover 230 may be covered by the first housing 210 and the second housing 220 without being exposed. In another example, when the electronic device 200 is in the folded state (e.g., fully folded state) as illustrated in FIG. 2, the hinge cover 230 may be exposed to the outside between the first housing 210 and the second housing 220. In another example, when the first housing 210 and the second housing 220 are in the intermediate state in which they are folded with a certain angle, the hinge cover 230 may be partially exposed to the outside between the first housing 210 and the second housing 220. In this case, however, the exposed area may be less than in the fully folded state. In an embodiment, the hinge cover 230 may include a curved surface.

According to an embodiment, the display 240 may be disposed in the space formed by the housing 201. For example, the display 240 may be seated in a recess formed by the housing 201 and form most of the front surface of the electronic device 200. Accordingly, the front surface of the electronic device 200 may include the display 240 and partial areas of the first housing 210 and the second housing 220 adjacent to the display 240. The rear surface of the electronic device 200 may include a the first rear cover 280, a partial area of the first housing 210 adjacent to the first rear cover 280, the second rear cover 290, and a partial area of the second housing 220 adjacent to the second rear cover 290.

According to an embodiment, the display 240 may refer to a display in which at least a partial area is deformable into a flat or curved surface. According to an embodiment, the display 240 may include a folding area 243, a first display area 241 disposed on one side of the folding area 243 (e.g., the left side of the folding area 243 illustrated in FIG. 1), and a second display area 242 disposed on the other side of the folding area 243 (e.g., the right side of the folding area 243 illustrated in FIG. 1).

However, the division of the display 240 into areas is exemplary, and the display 240 may be divided into a plurality of areas (for example, four or more areas or two areas) depending on the structure or function thereof. For example, although in the embodiment illustrated in FIG. 1, the area of the display 240 may be divided by the folding area 243 or the folding axis A extending parallel to the Y axis, the display 240 may be divided into areas based on a different folding area (e.g., a folding area parallel to the X axis) or a different folding axis (e.g., a folding axis parallel to the X axis) in an embodiment. According to an embodiment, the display 240 may be coupled to or disposed adjacent to a touch detection circuit, a pressure sensor capable of measuring the intensity (pressure) of touch, and/or a digitizer configured to detect a magnetic-field type stylus pen.

According to an embodiment, the first display area 241 and the second display area 242 may have an overall symmetrical shape with respect to the folding area 243. According to an embodiment, unlike the first display area 241, the second display area 242 may include a notch cut according to the presence of the sensor area 224. However, the second display area 242 may have a symmetrical shape with the first display area 241 in the other areas. In other words, the first display area 241 and the second display area 242 may include portions having a symmetrical shape and portions having an asymmetrical shape.

A description will be given of operations of the first housing 210 and the second housing 220 and each area of the display 240 according to the state (e.g., the unfolded or flat state, or the folded state) of the electronic device 200.

According to an embodiment, when the electronic device 200 is in the flat state (e.g., FIG. 1), the first housing 210 and the second housing 220 may form an angle of substantially 180 degrees, and the first display area 241 and the second display area 242 may be disposed to face substantially the same direction. For example, in the flat state, a surface of the first display area 241 and a surface of the second display area 242 may form an angle of 180 degrees and face the same direction (e.g., a front direction of the electronic device). The folding area 243 may form substantially the same plane as the first display area 241 and the second display area 242.

According to an embodiment, when the electronic device 200 is in the folded state (e.g., FIG. 2), the first housing 210 and the second housing 220 may be disposed to face each other. The surface of the first display area 241 and the surface of the second display area 242 of the display 240 may form a narrow angle (e.g., between 0 degrees and 10 degrees) and substantially face each other. At least a portion of the folding area 243 may be formed as a curved surface with a predetermined curvature.

According to an embodiment, when the electronic device 200 is in the intermediate state, the first housing 210 and the second housing 220 may be disposed at a certain angle. The surface of the first display area 241 and the surface of the second display area 242 of the display 240 may form an angle larger than in the folded state and smaller than in the flat state. At least a portion of the folding area 243 may be formed as a curved surface with a predetermined curvature, and have a curvature smaller than that in the folded state.

FIG. 3 is an exploded perspective view illustrating an electronic device according to an embodiment of the disclosure.

Referring to FIG. 3, the electronic device 200 may include the housing 201, the display 240, the hinge module 202, the battery 250, and the board unit 260. The housing 201 may include the first housing 210, the second housing 220, the first rear cover 280, and the second rear cover 290.

According to an embodiment, the housing 201 may include the first housing 210, the second housing 220, the hinge cover 230, the first rear cover 280, and the second rear cover 290. The configurations of the first housing 210, the second housing 220, the hinge cover 230, the first rear cover 280, and the second rear cover 290 in FIG. 3 may be wholly or partially identical to those of the first housing 210, the second housing 220, the hinge cover 230, the first rear cover 280, and the second rear cover 290 in FIG. 1 and/or FIG. 2. In an embodiment, the hinge module 202 providing the folding axis A may be disposed inside the housing 201 to rotatably connect the first housing 210 to the second housing 220.

According to an embodiment, the first housing 210 and the second housing 220 may be assembled to each other such that they are coupled to both sides of the hinge module 202. According to an embodiment, the first housing 210 may include a first support area 212 (e.g., a first support plate or a first support member) which may support components (e.g., a first circuit board 262 and/or a first battery 252) of the electronic device 200, and a first side wall 211 surrounding at least a portion of the first support area 212. The first side wall 211 may include the first side surface (e.g., the first side surface 211a in FIG. 2) of the electronic device 200. According to an embodiment, the second housing 220 may have a second support area 222 (e.g., a second support plate or a second support member) which may support components (e.g., a second circuit board 264 and/or a second battery 254) of the electronic device 200, and a second side wall 221 surrounding at least a portion of the second support area 222. The second side wall 221 may include the second side surface (e.g., the second side surface 221a in FIG. 2) of the electronic device 200.

According to an embodiment, the display 240 may include the first display area 241, the second display area 242, the folding area 243, and the sub-display 244. The configurations of the first display area 241, the second display area 242, and the folding area 243 in FIG. 3 may be wholly or partially identical to those of the first display area 241, the second display area 242, and the folding area 243 in FIG. 1 and/or FIG. 2. In an embodiment, the display 240 may include a display panel 245 and a window glass 247 (e.g., flexible glass), and the display panel 245 may be located on an inner side of the window glass 247 and thus protected from an external environment. The display panel 245 and/or the window glass 247 may be at least partially deformed between a planar shape and a curved shape depending on relative movement or rotation of the first housing 210 and the second housing 220.

According to an embodiment, the sub-display 244 may display a screen in a different direction from the display areas 241 and 242. For example, the sub-display 244 may output a screen in a direction opposite to the first display area 241. According to an embodiment, the sub-display 244 may be disposed on the first rear cover 280.

According to an embodiment, the battery 250 may include the first battery 252 disposed within the first housing 210 and the second battery 254 disposed within the second housing 220. According to an embodiment, the first battery 252 may be disposed on the first circuit board 262, and the second battery 254 may be disposed on the second circuit board 264.

According to an embodiment, the board unit 260 may include the first circuit board 262 disposed within the first housing 210 and the second circuit board 264 disposed within the second housing 220. According to an embodiment, the board unit 260 may include at least one flexible PCB (FPCB) 266 to electrically connect the first circuit board 262 to the second circuit board 264. According to an embodiment, at least a portion of the FPCB 266 may be disposed across the hinge module 202. According to an embodiment, the first circuit board 262 and the second circuit board 264 may be disposed inside a space formed by the first housing 210, the second housing 220, the first rear cover 280, and the second rear cover 290. Components for implementing various functions of the electronic device 200 may be disposed on the first circuit board 262 and the second circuit board 264.

According to an embodiment, the electronic device 200 may include a speaker module 208. According to an embodiment, the speaker module 208 may convert an electrical signal into sound. According to an embodiment, the speaker module 208 may be disposed inside the space formed by the first housing 210, the second housing 220, the first rear cover 280, and the second rear cover 290.

An exemplary configuration in which the first housing 210 and the second housing 220 are rotatably connected or coupled by the hinge module (or referred to as a ‘hinge structure’) has been described above. However, it is to be noted that this embodiment does not limit the electronic device according to an embodiment of the disclosure. For example, the electronic device according to an embodiment of the disclosure may include three or more housings, and “a pair of housings” in the above-described embodiment may mean “two of three or more housings rotatably coupled to each other.

Although the electronic device 200 disclosed in FIGS. 1 to 3 has the appearance of a foldable electronic device, the disclosure is not limited thereto. For example, the illustrated electronic device may be a bar type, plate type, or rollable electronic device. The term “rollable electronic device” may refer to an electronic device with a display (e.g. the display 240 in FIG. 3) which is bendable and thus at least partially wound or rolled into a housing (e.g., the housing 201 in FIG. 1). Depending on the user's needs, the rollable electronic device may be used by unfolding the display or exposing a larger area of the display to the outside and thus extending a screen display area.

In the following detailed description, a plurality of grooves or a direction in which the plurality of grooves extend and/or a plurality of grooves or a direction in which the plurality of grooves are arranged may be described with reference to the Cartesian coordinate system of FIG. 3. This extension direction or arrangement direction may be referred to as a ‘first direction’ or a ‘second direction’, which may be different from a ‘first direction’ or a ‘second direction’ referring to directions in which the front surface and rear surface of the housing of FIG. 1 or 2 are disposed. The ‘first direction’ or ‘second direction’ mentioned as the extension direction or arrangement direction may be accompanied by a reference numeral of the Cartesian coordinate system so that it may be distinguished from the ‘first direction’ or ‘second direction’ in the description given with reference to FIGS. 1 and 2.

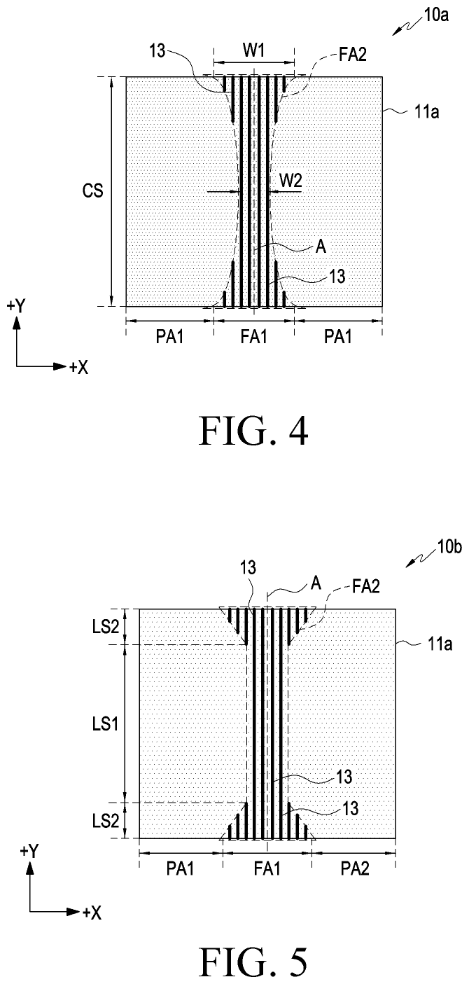

FIG. 4 is a plan view illustrating a flexible glass according to an embodiment of the disclosure.

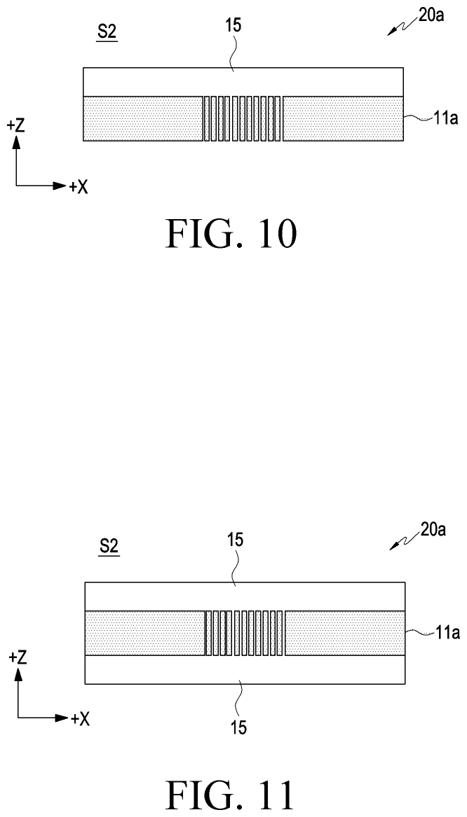

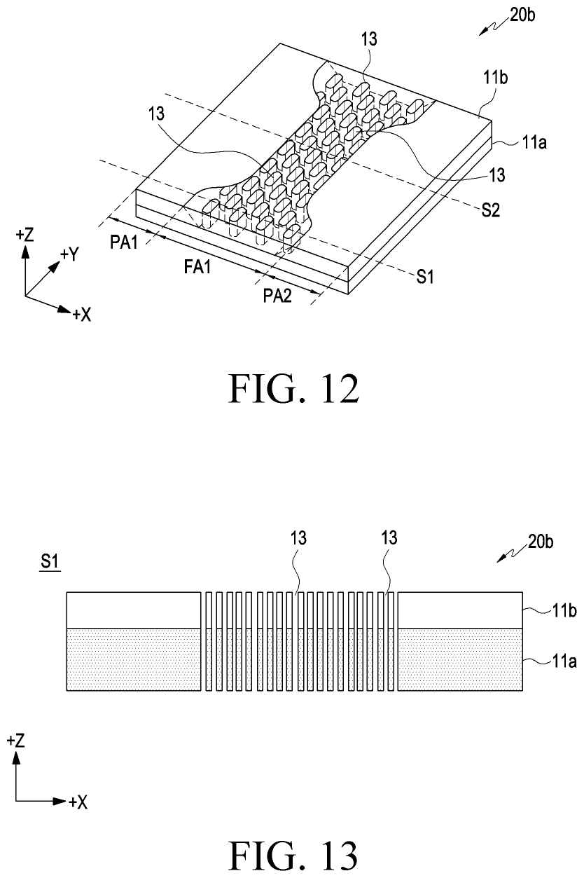

While the embodiment of FIG. 4 exemplifies a configuration in which a flexible glass 10a includes a glass layer 11a, to which the disclosure is not limited, the flexible glass 10a may further include a compensating material (layer) (e.g., a compensating material 15 in FIG. 10) to compensate a refractive index and/or a coating layer (e.g., a coating layer 11b in FIG. 12) to increase a strength. For example, various embodiments of the disclosure are not limited to any one of the embodiments described later, and under the condition that when the flexible glass 10a is a structure including an arrangement area FA2 in which a plurality of grooves or a plurality of holes 13 are arranged in at least a portion of a flexible area FA1 of the glass layer 11a and/or the coating layer 11b, and the arrangement area FA2 has a first width W1 and a second width W2 described later, the flexible glass 10a may include another additional coating or protective material (layer).

Referring to FIG. 4, the flexible glass 10a (e.g., the window glass 247 in FIG. 3) may include the flexible area FA1 and planar areas PA1 and PA2 provided on at least one side of the flexible area FA1. For example, the planar areas PA1 and PA2 may be provided on one side of the flexible area FA1 or on both sides of the flexible area FA1, respectively. When the flexible glass 10a is disposed as part of the flexible display 240 of FIG. 1 or 3, the flexible area FA1 may be disposed in correspondence with the folding area 243, for example. In an embodiment, the flexible area FA1 may be deformed into a planar shape and a curved shape with respect to a folding axis (e.g., the folding axis A in FIG. 1) extending in one direction. For example, the folding axis A of the electronic device (e.g., the electronic device 200 in FIGS. 1 to 3) may be the center of a radius of curvature, when the flexible area FA1 is deformed into a curved shape. However, various embodiments of the disclosure are not limited thereto, and the center of the radius of curvature when the flexible area FA1 is deformed into a curved surface may be set to various values according to the specifications of an electronic device to be produced.

According to an embodiment, the first planar area PA1 of the planar areas PA1 and PA2 may be disposed on the first housing (e.g., the first housing 210 in FIGS. 1 to 3), for example, to correspond to the first display area 241, and the second planar area PA2 may be disposed to correspond to the second display area 242. For example, the first planar area PA1 and the second planar area PA2 may be maintained in the shape of a flat plate regardless of a folding or unfolding operation of the electronic device 200. In an embodiment, when the electronic device 200 is in the folded state, the second planar area PA2 may be disposed to at least partially face the first planar area PA1, and when the electronic device 200 is in the flat state, the first planar area PA1 and the second planar area PA2 may be disposed side by side, each on one side of the other, with the flexible area FA1 interposed therebetween

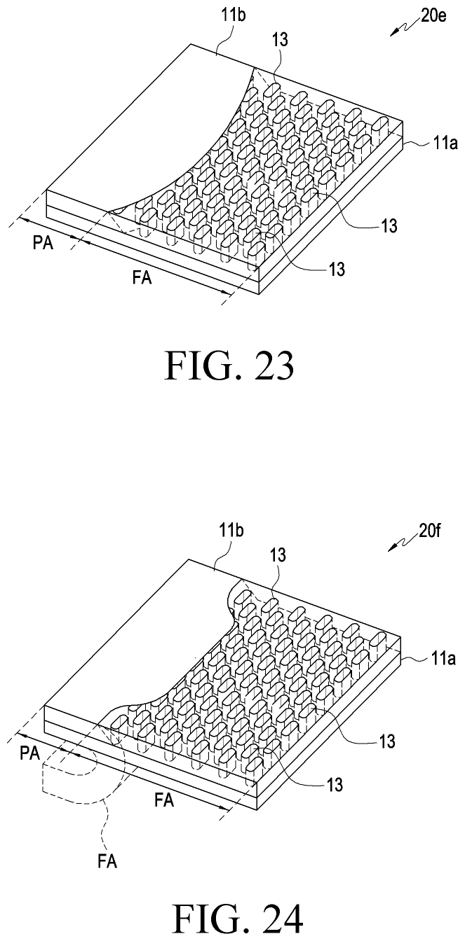

According to an embodiment, the second housing 220 may slide on the first housing 210 between a position at which the second housing 220 is accommodated in the first housing 210 and a position in which the second housing 220 at least partially protrudes from the first housing 210. In this case, the flexible glass 10a may include one planar area (e.g., a planar area PA in FIG. 23 or 24), and at least a portion of a flexible area (e.g., a flexible area FA in FIG. 23 or 24) may be accommodated into the first housing 210 or the second housing 220 according to sliding of the second housing 220. In the accommodated state, the flexible area FA may be deformed or move to at least partially face the planar area PA. For example, in the case of the configuration of a slidable or rollable electronic device, the flexible area FA may move between a state in which the flexible area FA is disposed side by side on one side of the planar area PA and a position at which the flexible area FA at least partially faces the planar area PA. The movement or deformation of the flexible area FA will be described with reference to FIG. 24.

According to an embodiment, as the thickness of the flexible glass 10a is greater, a relative displacement between the inner and outer surfaces thereof may be larger during a deformation operation. This relative displacement may cause stress within the flexible glass 10a, and the internal stress may be a cause of damage to the flexible glass 10a. For example, it may be useful to reduce the thickness of the flexible glass 10a to prevent damage while ensuring flexibility of the flexible glass 10a. In an embodiment, in protecting a display panel (e.g., the display panel 245 in FIG. 3) from external pressure or impact, the strength of the flexible glass 10a may be secured by increasing the thickness of the flexible glass 10a. For example, there may be difficulties in designing the thickness of the flexible glass 10a because the flexibility and protective performance of the flexible glass 10a are mutually exclusive.

According to an embodiment of the disclosure, as the flexible glass 10a includes a plurality of grooves or a plurality of holes 13 disposed in at least a portion (hereinafter referred to as an “arrangement area FA2”) of the flexible area FA1 (e.g., the flexible area FA in FIG. 23 or 24), flexibility may be secured in the deformation operation, and a sufficient thickness of the flexible glass 10a may be secured in an area where relatively low stress is generated even in the deformation operation. For example, as the plurality of grooves or the plurality of holes 13 are formed, an average thickness may be reduced in the flexible area FA1 so that flexibility of the flexible glass 10a is ensured in the folding or rolling operation, and a sufficient thickness of the flexible glass 10a may be ensured at least in the planar areas PA1 and PA2 (e.g., the planar area PA in FIG. 23 or 24), thereby reliably protecting the display panel 245.

According to an embodiment, in a plan view, the plurality of grooves or the plurality of holes 13 (hereinafter referred to as “hole(s)”) may extend along the direction of the folding axis A or the Y-axis direction and be arranged along a direction (e.g., the X-axis direction) intersecting the folding axis A. The holes 13 may be located substantially within the flexible area FA1, and may penetrate both surfaces (e.g., inner and outer surfaces) of the flexible glass 10a or be in the form of recesses recessed from one surface of the flexible glass 10a. In an area where the holes 13 are disposed, for example, in the arrangement area FA2, the average thickness of the flexible glass 10a may be reduced and thus more flexible than in the remaining areas. For example, as the arrangement area FA2 is disposed, internal stress caused by a relative displacement between the inner and outer surfaces of the flexible glass 10a may be suppressed in the deformation operation. The reduction of the internal stress caused by the deformation operation may ensure durability and reliability for the flexible glass 10a even during repeated deformation operations.

According to an embodiment, in an operation of deforming a flat plate-shaped flexible glass without the holes 13, internal stress in a deformed portion may tend to increase closer to edges intersecting the folding axis A. This is expected to be because, in the direction of the folding axis A, the internal stress at the center of the deformed portion (e.g., a portion indicated by the “second width W2”) is distributed over a larger area than the internal stress at an edge (e.g., a portion indicated by the “first width W1”). According to an embodiment of the disclosure, the arrangement area FA2 may have the first width W1 at the edges and the second width W2 at the center, which is smaller than the first width W1. For example, in the X-axis direction, more holes 13 may be formed at the edges than at the center of the flexible area FA1. In an embodiment, the first width W1 is at least 1.2 times the second width of the second width W2.

According to an embodiment, the flexible area FA1 may have a smaller average thickness and a greater flexibility at the edges of the flexible glass 10a than in the other portion (the center). For example, the internal stress caused by the deformation operation may be mitigated across the flexible area FA1, and more at the edges of the flexible glass 10a than at the center thereof. In an embodiment, the center of the flexible glass 10a may generate lower stress than the edges of the flexible glass 10a during the deformation operation, and a smaller number of holes 13 may be disposed at the center of the flexible glass 10a to suppress the degradation of protection performance.

As such, the thickness of the flexible glass 10a according to an embodiment of the disclosure may be reduced using the holes 13 or grooves in at least a portion of an area deformed into a curved shape (e.g., the folding area 243 in FIG. 3 or the flexible area FA1 in FIG. 4), thereby securing flexibility or durability in the deformation operation. In an embodiment, a sufficient thickness may be achieved by disposing a smaller number of holes or grooves in an area which is not deformed or an area that generates relatively small stress in the flexible glass 10a. For example, the display panel (e.g., display panel 245 in FIG. 3) may be reliably protected. In an embodiment, the flexible glass 10a may have partially different refractive indexes for transmitted light due to the formation of the holes or grooves 13. The flexible glass 10a may compensate for the partial refractive index difference by including a compensating material (layer) (e.g., the compensating material 15 in FIG. 10) filled in at least some of the holes 13a or grooves. In an embodiment, the compensating material (layer) includes at least one of optically transparent polymer, PET (Polyethylene Terephthalate), PC (Polycarbonate), acrylic resin, and/or silicone resin.

According to an embodiment, an edge of the arrangement area FA2, for example, a boundary between the flexible area FA1 or the arrangement area FA2 in the flexible glass 10a and the remaining area may include a curved section CS. The curved section CS may have a shape that gradually increases the width of the arrangement area FA2 measured in the X-axis direction from the center (e.g., the portion indicated by the “second width W2”) to an edge (e.g., the portion indicated by the “first width W1”) on one side thereof. In an embodiment, in the direction of the folding axis A, both ends of the arrangement area FA2 may have the first width W1 greater than the second width W2. For example, in the plan view of FIG. 4, more holes 13 may be arranged along the X-axis direction at both ends than at the center of the arrangement area FA2, while having the same width (e.g., a width measured along the X-axis direction). In an embodiment, the same number of holes 13 may be arranged at the center and both ends of the arrangement area FA2, and in this case, the width of the holes 13 themselves (e.g., the width measured along the X-axis direction) may gradually increase toward both ends of the arrangement area FA2.

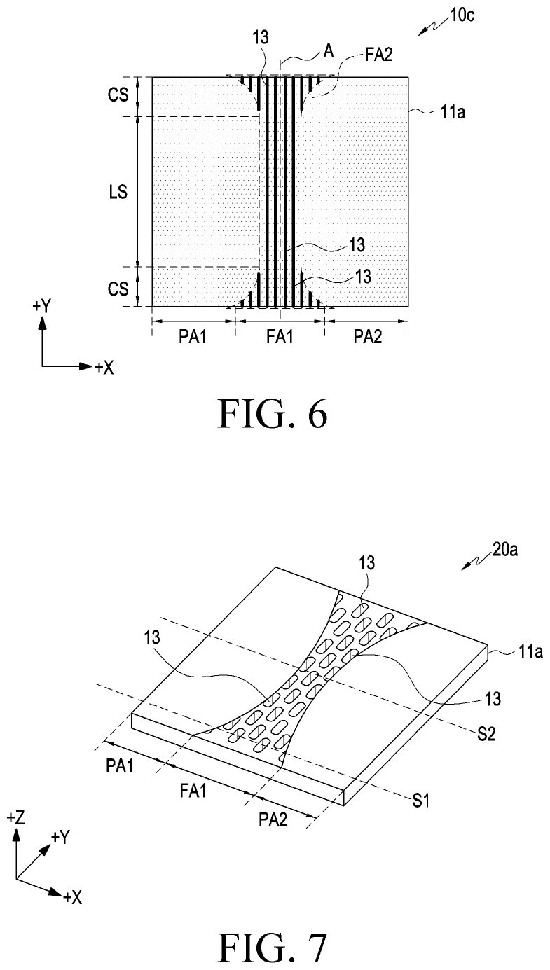

According to an embodiment, the edge of the arrangement area FA2 may include straight section(s), or may be shaped as a combination of curved and straight sections. This will be described with reference to FIGS. 5 and 6.

FIG. 5 is a plan view illustrating a flexible glass according to an embodiment of the disclosure. FIG. 6 is a plan view illustrating a flexible glass according to another embodiment of the disclosure.

Referring to FIG. 5, an edge of the arrangement area FA2 may include first straight section(s) LS1 and second straight section(s) LS2. The first straight section(s) LS1 may be substantially parallel to, for example, the direction of the folding axis A or the Y-axis direction, and the second straight section(s) LS2 may be formed inclined with respect to the first straight section(s) LS1 so that the first width (e.g., the first width W1 in FIG. 4) is greater than the second width (e.g., the second width W2 in FIG. 4) at an edge of the flexible glass 10b. For example, the second straight section(s) LS2 may be disposed to be inclined in a direction that increases the width of the arrangement area FA2 toward the edge of the flexible glass 10b.

Referring to FIG. 6, an edge of the arrangement area FA2 may include straight section(s) LS and curved sections(s) CS. The straight section(s) LS may be substantially parallel to, for example, the direction of the folding axis A or the Y-axis direction, and the curved section(s) CS may extend from the straight section(s) LS in a direction or shape in which the first width (e.g., the first width W1 in FIG. 4) is greater than the second width (e.g., the second width W2 in FIG. 4) at the edge of the flexible glass 10c. For example, the curved section(s) CS may have a shape that increases the width of the arrangement area FA2 toward an edge of the flexible glass 10c.

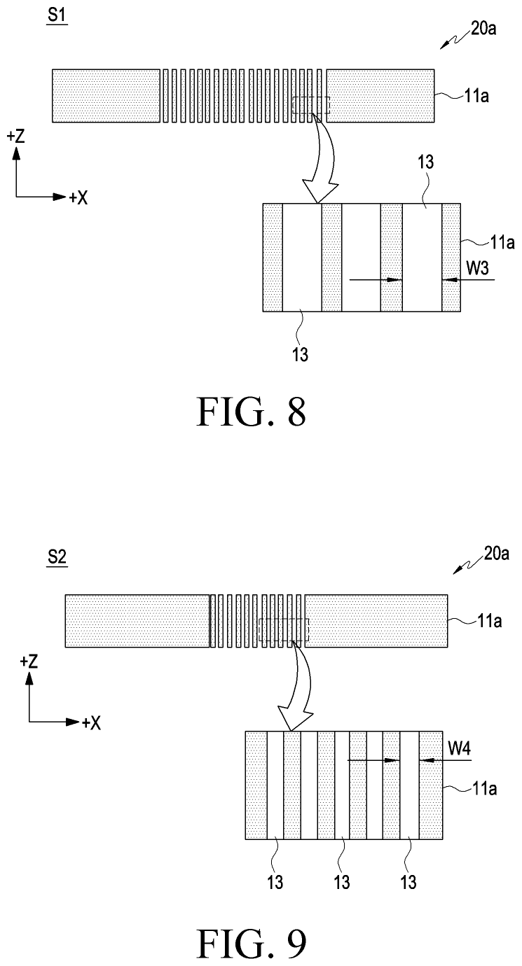

FIG. 7 is a perspective view illustrating a flexible glass according to an embodiment of the disclosure. FIG. 8 is a cross-sectional view illustrating the flexible glass, taken along line S1 in FIG. 7. FIG. 9 is a cross-sectional view illustrating the flexible glass, taken along line S2 in FIG. 7.

A flexible glass 20a of FIGS. 7 to 9 may include a plurality of holes 13 that penetrate both surfaces of the glass layer 11a in at least a portion of the flexible area FA1, and an area (e.g., the arrangement area FA2 in FIG. 4) in which the holes 13 are formed may include curved sections (e.g., the curved sections CS in FIG. 4) and have a greater width (e.g., a width measured along the X-axis direction) at edges or both ends indicated by ‘S1’ than at a center indicated by ‘S2’. For example, the average thickness of the flexible glass 20a may be greater at the center of the flexible area FA1 than at both ends thereof. In an embodiment, the average thickness of the flexible glass 20a may be smaller in the flexible area FA1 than in the planar areas PA1 and PA2. For example, the flexible area FA1 may have a higher flexibility than the planar areas PA1 and PA2, while still being durable to repeated deformations. According to an embodiment, the flexible area FA1 may have higher flexibility at the edges thereof than at the center thereof, thereby mitigating or suppressing internal stress caused by a deformation operation. This arrangement area FA2 has been described before with reference to FIGS. 4 to 6, and thus its detailed description will be avoided herein.

According to an embodiment, the number of holes 13 arranged along the X-axis direction at the center of the flexible area FA1 may be substantially equal to those at both ends of the flexible area FA1. In this case, as illustrated in FIGS. 7 and 8, a third width W3 of the holes 13 at both ends of the flexible area FA1 may be greater than a fourth width W4 of the holes 13 at the center of the flexible area FA1. For example, even though the same number of holes 13 are arranged along the X-axis direction at the center and both ends of the flexible area FA1, the arrangement area FA2 may have the first width W1 at both ends thereof greater than the second width W2 at the center thereof, and the average thickness of the flexible glass 20a may be smaller at both ends of the arranged area FA2 than at the center thereof. As such, the number of holes 13 arranged in the X-axis direction, or the width (e.g., the third width W3 or the fourth width W4 in FIGS. 8 and 9) of the hole(s) 13 based on their positions may be designed appropriately within the arrangement area FA2. In an embodiment, in the direction intersecting the folding axis A, the spacing between the holes 13 may gradually decrease toward the edges (e.g., both ends) of the arrangement area FA2. For example, as the holes 13 are more densely arranged closer to both ends of the arrangement area FA2, the thickness of the flexible glass may be smaller at both ends of the arrangement area FA2 than in the other portions of the arrangement area FA2.

In the following description of embodiments, a detailed description of a configuration that may be readily understood from the preceding embodiments will be avoided. An additional embodiment may be implemented by selectively combining some of the configurations of the preceding embodiments and/or subsequent embodiments. For example, the arrangement area FA2 of the above-described embodiments or the embodiments described below may be changed to any one of the shapes of the curved sections or straight sections illustrated in FIGS. 4 to 6 to implement an additional embodiment. In an embodiment, a coating layer described later (e.g., the coating layer 11b in FIG. 12) may be combined with a glass layer of an embodiment to implement a flexible glass, depending on the specifications of an actual electronic device to be fabricated.

FIGS. 10 and 11 are cross-sectional views illustrating modified examples of the flexible glass of FIG. 7.

Referring to FIGS. 10 and 11, the flexible glass 20a may further include a protective material 15 filled in at least some of the holes 13. According to an embodiment, the protective material 15 may be further disposed on one or both surfaces of the flexible glass 20a (e.g., the glass layer 11a), and thus referred to as a “protective material layer”. In view of the formation of the holes 13, the flexible glass 20a or the glass layer 11a may have a partial refractive index deviation. This refractive index deviation may cause the degradation of image quality, when the flexible glass 20a is coupled to the display panel 245. Because the flexible glass 20a according to an embodiment of the disclosure includes the compensating material 15 filled in at least some of the holes 13, the refractive index deviation caused by the holes 13 may be compensated for, and the degradation of image quality may be suppressed. In an embodiment, the compensating material 15 may be applied to one or both surfaces of the glass layer 11a.

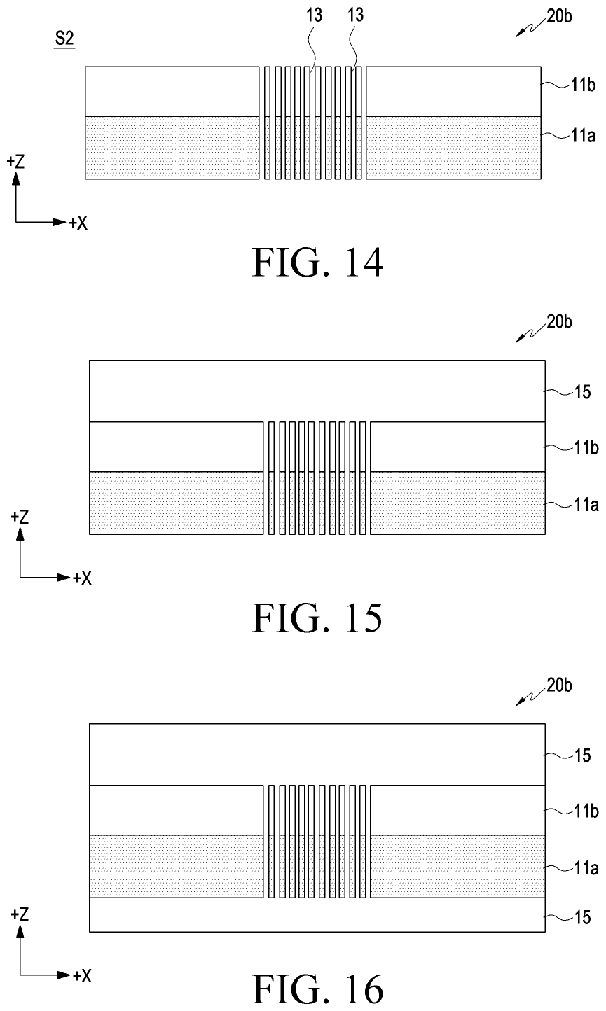

FIG. 12 is a perspective view illustrating a flexible glass according to an embodiment of the disclosure. FIG. 13 is a cross-sectional view illustrating the flexible glass, taken along line S1 of FIG. 12. FIG. 14 is a cross-sectional view illustrating the flexible glass, taken along line S2 of FIG. 12.

Referring to FIGS. 12 to 14, a flexible glass 20b may include an arrangement area (e.g., the arrangement area FA2 in FIGS. 4 to 6) including a combination of straight and curved sections, and further include the coating layer 11b provided on at least one surface of the glass layer 11a. In an embodiment, the coating layer 11b may increase the surface hardness of the flexible glass 20b, thereby suppressing surface damage such as scratches. For example, the coating layer 11b may be provided at least on an outer surface of the flexible glass 20b. According to an embodiment, the holes 13 may be formed to penetrate from one surface of the flexible glass 20b (e.g., an outer surface of the coating layer 11b) to the other surface of the flexible glass 20b (e.g., an outer surface of the glass layer 11a). For example, the coating layer 11b may increase the surface hardness of the flexible glass 20b, while mitigating a decrease in the flexibility of the flexible area FA2 caused by the coating layer 11b.

FIGS. 15 and 16 are cross-sectional views illustrating modified examples of the flexible glass of FIG. 12.

Referring to FIGS. 15 and 16, the flexible glass 20b may further include the protective material 15 filled in at least some of the holes 13 to compensate for a refractive index deviation caused by the holes 13. In an embodiment, the compensating material 15 may be applied to a surface of the glass layer 11a and/or a surface of the coating layer 11b.

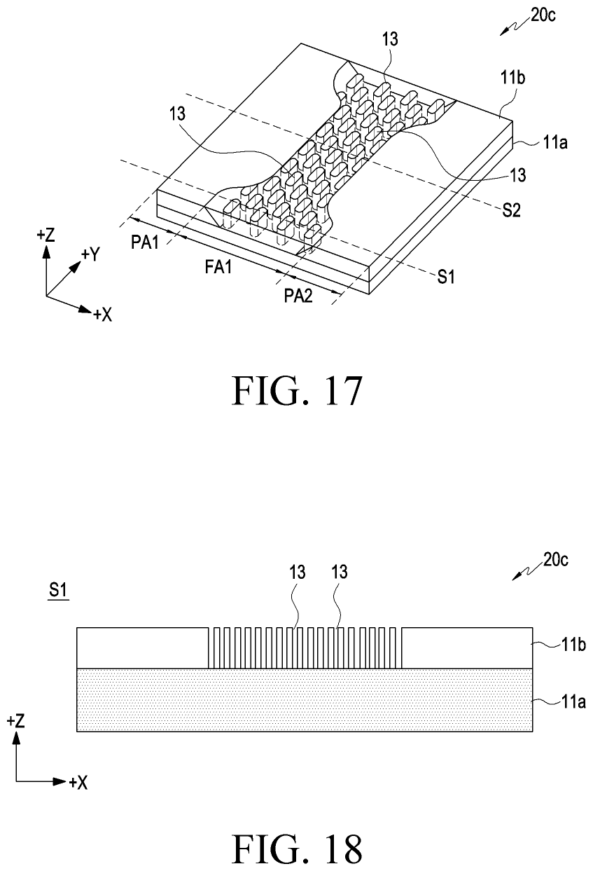

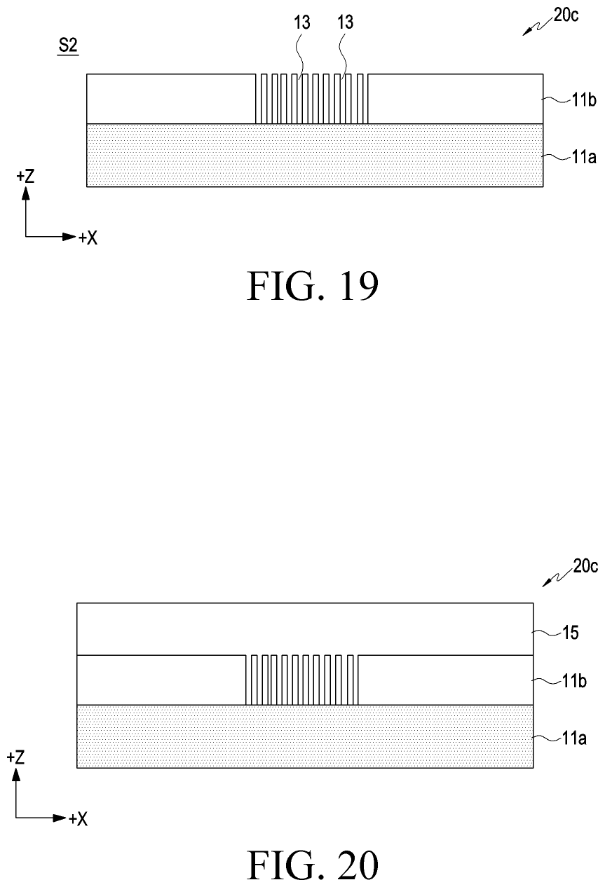

FIG. 17 is a perspective view illustrating a flexible glass according to another embodiment of the disclosure. FIG. 18 is a cross-sectional view illustrating the flexible glass, taken along line S1 of FIG. 17. FIG. 19 is a cross-sectional view illustrating the flexible glass, taken along line S2 of FIG. 17. FIG. 20 is a cross-sectional view illustrating a modified example of the flexible glass of FIG. 17.

Referring to FIGS. 17 to 20, when a flexible glass 20c includes the coating layer 11b, the holes 13 may be formed in the coating layer 11b, and the glass layer 11a may have a flat plate shape that does not include the holes 13 or grooves. In an embodiment, when the glass layer 11a is in a flat plate shape without holes, a structure indicated by reference numeral “13” may be substantially a recess. The depth of the holes 13 may be selected appropriately, for example, taking into account factors such as the overall thickness of the flexible glass 20c, the ease of processing the glass layer 11a to form the holes 13, and/or the flexibility of the flexible glass 20c. The flexible glass 20c may further include the protective material 15 filled in at least some of the holes 13, thereby compensating for a refractive index deviation caused by the holes 13. In an embodiment, the compensating material 15 may be further applied to at least one surface of the glass layer 11a.

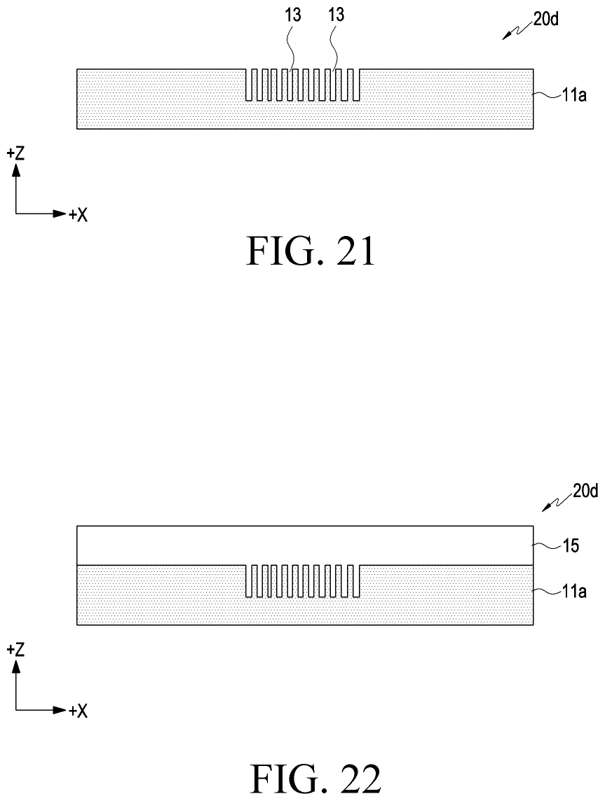

FIG. 21 is a cross-sectional view illustrating a flexible glass according to another embodiment of the disclosure. FIG. 22 is a cross-sectional view illustrating a modified example of the flexible glass of FIG. 21.

Referring to FIGS. 21 and 22, a flexible glass 20d may include recesses 13 recessed into a surface of the glass layer 11a. For example, the through holes of the preceding embodiments may be replaced with grooves with one ends closed in the flexible glass 20d of this embodiment. To increase the flexibility of the flexible glass 20d in an arrangement area (e.g., the arrangement area FA2 in FIGS. 4 to 6), the thickness of the flexible glass 20d may be adjustable in a partial area (e.g., the flexible area FA1 or the arrangement area FA2 in FIGS. 4 to 6) of the flexible glass 20d by forming holes or the grooves 13 in the partial area, and the depth of the grooves 13 may be selected appropriately, taking into account the actual thickness of the flexible glass 20d and stress or flexibility in a deformation operation. As described in the preceding embodiments, these holes or grooves may substantially penetrate the glass layer 11a according to the selected depth. In the illustrated embodiment, the flexible glass 20d may further include the compensating material 15 filled in at least some of the grooves 13, and when the compensating material 15 is applied to one surface of the glass layer 11a, the compensating material 15 may be disposed on a surface where the internal spaces of the grooves 13 are exposed to the outside.

FIGS. 23 and 24 are perspective views illustrating modified examples of a flexible glass according to an embodiment of the disclosure.

Referring to FIGS. 23 and 24, in flexible glasses 20e and 20f, an area on one side thereof may be set as a planar area PA and an area on the other side thereof may be set as a flexible area FA including the holes (or grooves) 13. A boundary between the area (e.g., the arrangement area FA2 in FIGS. 4 to 6) in which the holes 13 are formed and an area in which the holes 13 are not formed may include at least one of a curved section or a straight section. The flexible glasses 20e and 20f each including one flat area PA and one flexible area FA may be useful for providing flexibility and strength in the configuration of a slidable or rollable electronic device. For example, when the second housing 220 of the electronic device 200 in FIGS. 1 to 3 is configured to slide on the first housing 210 and be selectively accommodated in the first housing 210, the planar area PA of the flexible glasses 20e and 20f (e.g., the flexible display 240 in FIG. 3) may be maintained visually exposed to the outside of the electronic device 200, and in a sliding operation, the flexible area FA may be gradually accommodated into the electronic device 200 or visually exposed to the outside of the electronic device 200 from an edge of either the first housing 210 or the second housing 220. When exposed to the outside, the flexible area FA may be disposed or aligned on substantially the same plane with the planar area PA.

In FIG. 24, a flexible area FA indicated by a dotted line represents an exemplary shape in the accommodated state where the flexible area FA may be disposed to be at least partially face the planar area PA. However, it should be noted that various embodiments of the disclosure are not limited thereto, and another structure or electronic component may be disposed between the flexible area FA and the planar area PA in the accommodated state. In the accommodated state, the center of the flexible glasses 20e and 20f may have a curved surface, and in an operation of gradual exposure to the outside, the curved portion may gradually move toward an edge of the flexible area FA, such that the flexible area FA is gradually aligned on the same plane as the planar area PA.

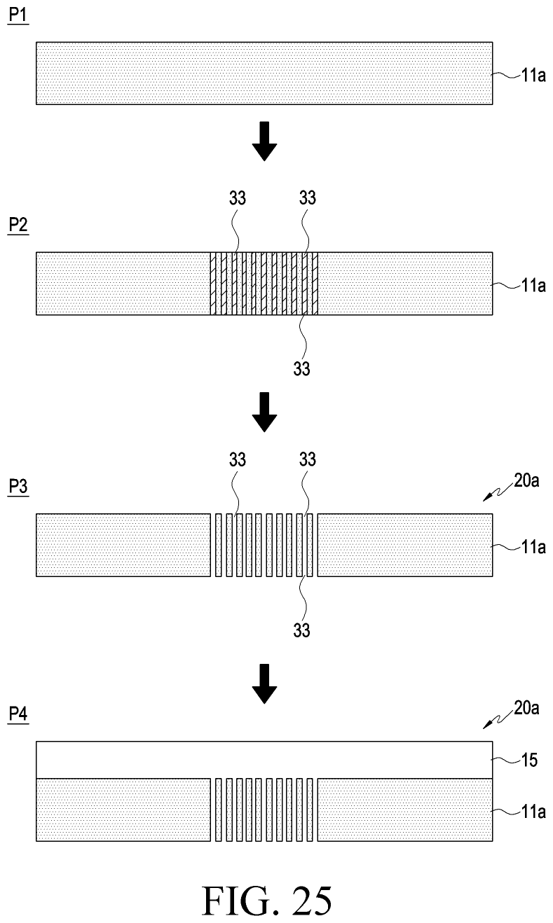

FIG. 25 is a diagram illustrating a process for fabricating a flexible glass according to an embodiment of the disclosure.

Referring to FIG. 25, operation P1 may be an operation for preparing the glass layer 11a, in which a sheet or film of a glass material may be fabricated. The glass layer 11a may be fabricated to a thickness that meets the specifications of an electronic device to be fabricated. In an embodiment, operation P2 may be a laser irradiation operation in which the glass layer 11a may be partially deteriorated by irradiating a laser onto a portion in which holes or grooves are to be formed (e.g., a portion indicated by reference numeral ‘33’). In operation P2, the flexibility of an arrangement area (e.g., the arrangement area FA2 in FIGS. 4 to 6) and/or a flexible area (e.g., the flexible area FA1 in FIGS. 4 to 6) may be substantially determined. In an embodiment, operation P3 may be an etching or cleaning operation, in which deteriorated portions of the glass layer 11a may be substantially removed and holes (e.g., the holes 13 in FIGS. 4 to 6) and/or grooves may be formed, by etching or cleaning. Operation P4 may be understood as, for example, a finishing operation, in which a coating layer (e.g., the coating layer 11b in FIG. 12) and/or a compensating material (e.g., the compensating material 15 in FIG. 10) is disposed. While a structure with the holes 13 and/or the compensating material 15 formed on one surface of the glass layer 11a is shown in the illustrated embodiment, it will be readily understood from the embodiments described above that an operation for disposing the compensating material 15 or forming the coating layer 11b on both surfaces of the glass layer 11a may be added.

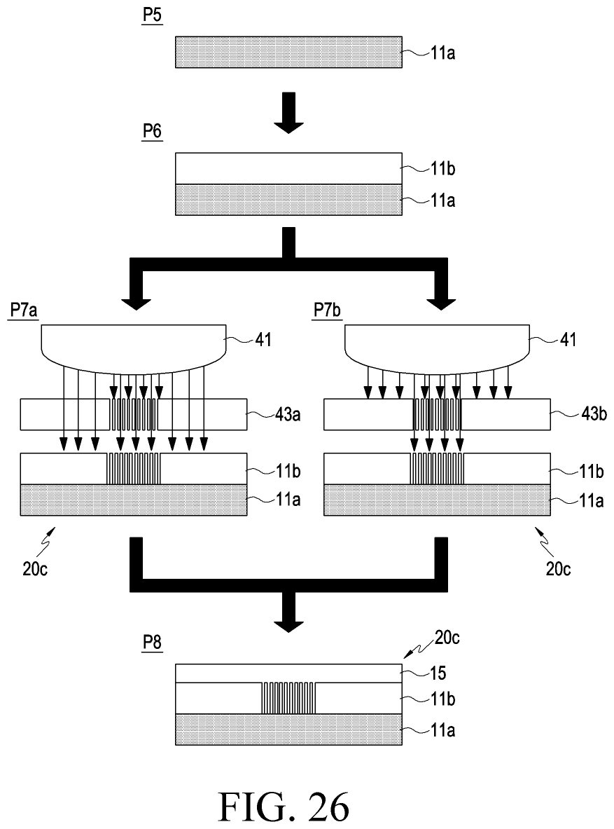

FIG. 26 is a diagram illustrating another exemplary process for fabricating a flexible glass according to an embodiment of the disclosure.

FIG. 26 illustrates, for example, a process for fabricating the flexible glass 20c further including the coating layer 11b. Referring to FIG. 26, operation P5 may be an operation for preparing the glass layer 11a, in which a sheet or film of a glass material is fabricated. The glass layer 11a may be fabricated to a thickness that meets the specifications of an electronic device to be fabricated. In an embodiment, the glass layer 11a may be processed to include the holes or grooves 13 by the fabrication process of FIG. 25. In an embodiment, the glass layer 11a of FIG. 26 may be substantially the flexible glass 20a fabricated in FIG. 25.

According to an embodiment, operation P6 is an operation for forming the coating layer 11b on a surface of the glass layer 11a, in which the coating layer 11b may be formed by applying and/or curing a polymeric material such as a ultraviolet (UV)-curable resin to the surface of the glass layer 11a. Operations P7a and P7b are operations for forming the holes 13 in the coating layer 11b, in which a photolithography process may be used. In operation P7a, the holes 13 may be formed by irradiating light onto the remaining portion of the coating layer 11b except for a portion to be removed, using a light source 41 and a first pattern mask 43a and then removing the portion of the coating layer 11b by etching. For example, in operation P7a, a portion of the coating layer 11b exposed to light from the light source 41 may remain on the surface of the glass layer 11a. In operation P7b, the holes 13 may be formed by irradiating light onto the portion to be removed, using the light source 41 and a second pattern mask 43b, and then removing the exposed portion by etching. In this photolithography process, the pattern masks 43a and 43b may be appropriately selected according to the material of the coating layer 11b. According to an embodiment, when the glass layer 11a is a structure in which holes or grooves are formed, the holes 13 formed in the coating layer 11b may be arranged substantially to correspond to the holes on the glass layer 11a. Operation P8 may be understood as, for example, a finishing operation, in which the compensating material 15 is disposed. In the illustrated embodiment, the compensating material 15 may be applied to one surface of the flexible glass 20c (e.g., the outer surface of the coating layer 11b), so that the compensating material 15 is also filled in the holes 13.

A flexible glass (e.g., the flexible glasses 10a, 10b and 10c in FIGS. 4 to 6) according to an embodiment may be disposed as a portion of a flexible display (e.g., the display 240 in FIG. 1 or 3) and protect a display panel (e.g., the display panel 245 in FIG. 3). In an embodiment, a flexible area (e.g., the flexible area FA1 in FIGS. 4 to 6) of the flexible glass may be disposed to correspond to a folding area (e.g., the folding area 243 in FIG. 1 or 3) and deformable into a planar shape and a curved shape around a folding axis (e.g., the folding axis A in FIG. 1) according to movement or pivoting of a first housing (e.g., the first housing 210 in FIG. 1 or 3) and a second housing (e.g., the second housing 220 in FIG. 1 or 3). According to an embodiment, as a plurality of holes (e.g., the holes 13 in FIGS. 4 to 6) or recesses are disposed in at least a portion (e.g., the arrangement area FA2 in FIGS. 4 to 6) of the flexible area, the flexibility of the flexible area may be improved. According to an embodiment, the display panel may be stably protected by securing a sufficient strength or thickness of the flexible glass in an area which is not deformed (e.g., the planar areas PA1 and PA2 in FIGS. 4 to 6).

As described above, according to an embodiment of the disclosure, a flexible glass comprises a flexible area including a first side edge and a second side edge, and a lattice pattern area provided between the first side edge and the second side edge, the flexible area configured to be movable between a planar shape and a curved shape with respect to at least one folding axis extending along a first direction, and a planar area provided on at least one side of the flexible area. In an embodiment, the lattice pattern area includes a plurality of first holes filled with a material for compensating a refractive index deviation of transmitted light in the flexible area. In an embodiment, a first width of the lattice pattern area corresponding to at least one of the first side edge or the second side edge of the flexible area intersecting the at least one folding axis may be greater than a second width of the lattice pattern area at a center between the first side edge and the second side edge of the flexible area.

According to an embodiment of the disclosure, the first width of the lattice pattern area may be at least 1.2 times the second width of the lattice pattern area.

According to an embodiment of the disclosure, an edge of the lattice pattern area may comprise at least one of a straight section or a curved section.

According to an embodiment of the disclosure, a width of the plurality of first holes along a second direction intersecting the first direction may increase based on a distance to the at least one of the first side edge or the second side edge.

According to an embodiment of the disclosure, a spacing between two adjacent first holes among the plurality of first holes may decrease based on a distance to the at least one of the first side edge or the second side edge.

According to an embodiment of the disclosure, the compensating material may be further provided on at least one surface of the flexible glass.

According to an embodiment of the disclosure, the flexible glass may further comprise a glass layer provided from the flexible area to the planar area, and a coating layer provided on at least one surface of the glass layer.

According to an embodiment of the disclosure, the plurality of first holes may be provided in the coating layer.

According to an embodiment of the disclosure, the plurality of first holes may be provided in the coating layer, and the glass layer may comprise a plurality of second holes corresponding to the plurality of first holes.

According to an embodiment of the disclosure, the flexible glass may further comprise a compensating material provided in at least some of the plurality of second holes, and the compensating material may be configured to compensate for a refractive index deviation of transmitted light in the flexible area.

According to an embodiment of the disclosure, the planar area may be provided on both sides of the flexible area, respectively, and as the flexible area is moved, the planar areas may be configured to be disposed side by side, each on one side of the other, with the flexible area disposed therebetween, or be disposed to at least partially face each other.

According to an embodiment of the disclosure, the flexible area may be provided side by side on one side of the planar area and configured to be moved to a position in which the flexible area at least partially faces the planar area at a specified spacing.

According to an embodiment of the disclosure, an electronic device comprises a first housing, a second housing coupled to the first housing and configured to move with respect to the first housing, and a flexible display comprising a first display area provided on the first housing, and a folding area extending from the first display area and configured to be movable into a planar shape and a curved shape according to movement of the second housing. In an embodiment the flexible display may comprise the flexible glass as described above. In an embodiment, the flexible area of the flexible glass may be provided in the folding area.

According to an embodiment of the disclosure, the electronic device may further comprise a hinge providing the at least one folding axis, corresponding to the folding area, and pivotably connecting the first housing and the second housing to each other. In an embodiment, the second housing may be configured to move with respect to the at least one folding axis between a folded state in which the second housing faces the first housing and a flat state in which the second housing moves from the folded state by a specified angle.

According to an embodiment of the disclosure, the flexible display may further comprise a second display area extending from the folding area and provided on the second housing. In an embodiment, in the folded state, the second display area may be at least partially faces the first display area.

According to an embodiment of the disclosure, a flexible glass (e.g., the window glass 247 in FIG. 3 or the flexible glasses 10a, 10b and 10c in FIGS. 4 to 6) may include a flexible area (e.g., the flexible area FA1 in FIGS. 4 to 6) deformable into a planar shape and a curved shape with respect to at least one folding axis (e.g., the folding axis A in FIG. 1 or FIGS. 4 to 6) extending along a first direction (e.g., the Y-axis direction in FIGS. 4 to 6), a planar area (e.g., the planar areas PA1 and PA2 in FIGS. 4 to 6) provided on at least one side of the flexible area, and a plurality of first recesses or a plurality of first holes (e.g., the holes 13 in FIGS. 4 to 9, FIGS. 12 to 14, FIGS. 17 to 19, FIG. 21, FIG. 23, and/or FIG. 24) disposed in at least a portion of the flexible area. The first recesses or the first holes may extend along the first direction and be arranged along a second direction (e.g., the X-axis direction in FIGS. 4 to 6) intersecting the first direction in at least a portion (hereinafter, referred to as ‘arrangement area (e.g., the arrangement area FA2 in FIGS. 4 to 6)’) of the flexible area. A first width (e.g., the first width W1 in FIG. 4) of the arrangement area measured along the second direction in at least one of edges of the flexible area intersecting the folding axis may be set to be greater than a second width (e.g., the second width W2 in FIG. 4) of the arrangement area measured at a center between the edges.

According to an embodiment, an edge of the arrangement area may include at least one of a straight section (e.g., the straight sections LS1, LS2 and LS in FIG. 5 or 6) or a curved section (e.g., the curved section CS in FIG. 4 or 6).

According to an embodiment, a width of the plurality of first grooves or the plurality of first holes measured along the second direction may gradually increase toward the edge (refer to the third width W3 and the fourth width F4 in FIGS. 8 and 9).

According to an embodiment, a spacing between two adjacent first grooves among the plurality of first grooves or a spacing between two adjacent first holes among the plurality of first holes may gradually decrease toward the edge.

According to an embodiment, the flexible glass may further include a compensating material (e.g., the compensating material 15 in FIG. 10) filled in the plurality of first grooves or the plurality of first holes, and the compensating material may be configured to compensate for a refractive index deviation of transmitted light at least in the flexible area.

According to an embodiment, the compensating material may be further disposed on at least one surface of the flexible glass.

According to an embodiment, the flexible glass may further include a glass layer (e.g., the glass layer 11a in FIGS. 12 to 14) provided from the flexible area to the planar area, and a coating layer (e.g., the coating layer 11b in FIGS. 12 to 14) disposed on at least one surface of the glass layer.

According to an embodiment, the plurality of first grooves or the plurality of first holes may be formed in the coating layer.

According to an embodiment, the plurality of first grooves or the plurality of first holes may be formed in the coating layer, and the glass layer may include second grooves or second holes disposed to correspond to the plurality of first grooves or the plurality of first holes.

According to an embodiment, the flexible glass may further include a compensating material filled in at least some of the plurality of first grooves, the plurality of first holes, the second grooves, or the second holes, and the compensating material may be configured to compensate for a refractive index deviation of transmitted light at least in the flexible area.

According to an embodiment, the planar area may be disposed on each of both sides of the flexible area, and the planar areas may be configured to be disposed side by side, each on one side of the other, with the flexible area interposed between the planar areas or to be disposed to at least partially face each other, as the flexible area is deformed.

According to an embodiment, the flexible area may be configured to be disposed side by side on one side of the planar area or to be deformed or moved to a position in which the flexible area at least partially faces the planar area at a specified spacing.

An electronic device (e.g., the electronic device 200 in FIGS. 1 to 3) according to an embodiment of the disclosure may include a first housing (e.g., the first housing 210 in FIGS. 1 to 3), a second housing (e.g., the second housing 220 in FIGS. 1 to 3) coupled to the first housing and configured to move or pivot with respect to the first housing, and a flexible display (e.g., the flexible display 240 in FIG. 1 or 3) including a first display area (e.g., the first display area 241 in FIG. 1 or 3) disposed on the first housing, and a folding area (e.g., the folding area 243 in FIG. 1 or 3) extending from the first display area and configured to be deformed into a planar shape and a curved shape according to movement or pivoting of the second housing. The flexible display may include the above-described flexible glass (e.g., the window glass 247 or the flexible glasses 10a, 10b and 10c in FIGS. 3 to 6), and the flexible area of the flexible glass may be disposed in the folding area.

According to an embodiment, the electronic device may further include a hinge module (e.g., the hinge module 202 in FIG. 3) providing the folding axis, disposed to correspond to the folding area, and pivotably connecting the first housing and the second housing to each other, and the second housing may be configured to pivot with respect to the folding axis between a folded state in which the second housing faces the first housing and a flat state in which the second housing pivots from the folded state by a specified angle.

According to an embodiment, the flexible display may further include a second display area (e.g., the second display area 242 in FIG. 1 or 3) extending from the folding area and disposed on the second housing, and in the folded state, the second display area may be disposed to at least partially face the first display area.

An electronic device (e.g., the electronic device 200 in FIGS. 1 to 3) according to an embodiment of the disclosure may include a first housing (e.g., the first housing 210 in FIGS. 1 to 3), a second housing (e.g., the second housing 220 in FIGS. 1 to 3) coupled to the first housing and configured to move or pivot with respect to the first housing, and a flexible display (e.g., the flexible display 240 in FIG. 1 or 3) including a first display area (e.g., the first display area 241 in FIG. 1 or 3) disposed on the first housing and a folding area (e.g., the folding area 243 in FIG. 1 or 3) extending from the first display area and configured to be deformed into a planar shape and a curved shape according to movement or pivoting of the second housing. The flexible display may include a display panel (e.g., the display panel 245 in FIG. 3), a flexible glass (e.g., the flexible glasses 10a, 10b and 10c in FIGS. 4 to 6) including a planar area (e.g., the planar areas PA1 and PA2 in FIGS. 4 to 6) disposed in the first display area and a flexible area (e.g., the flexible area FA1 in FIGS. 4 to 6) disposed in the folding area, and a plurality of first recesses or a plurality of first holes (e.g., the holes 13 in FIGS. 4 to 9, FIGS. 12 to 14, FIGS. 17 to 19, FIG. 21, FIG. 23, and/or FIG. 24) disposed in at least a portion of the flexible area. The first recesses or the first holes may extend along a first direction (e.g., the Y-axis direction in FIGS. 4 to 6) and be arranged along a second direction (e.g., the X-axis direction in FIGS. 4 to 6) intersecting the first direction in at least a portion (hereinafter, referred to as ‘arrangement area (e.g., the arrangement area FA2 in FIGS. 4 to 6)’) of the flexible area. A width (e.g., the first width W1 or the second width W2 in FIG. 4) of the arrangement area measured along the second direction may be set to be greater in at least one of edges of the flexible area intersecting the first direction axis than at a center between the edges.

According to an embodiment, the electronic device may further include a hinge module (e.g., the hinge module 202 in FIG. 3) providing a folding axis (e.g., the folding axis A in FIG. 1 or FIGS. 4 to 6) extending along the first direction, disposed to correspond to the folding area, and pivotably connecting the first housing and the second housing to each other, and the second housing may be configured to pivot with respect to the folding axis between a folded state in which the second housing faces the first housing and a flat state in which the second housing pivots from the folded state by a specified angle.

According to an embodiment, the flexible display may further include a second display area (e.g., the second display area 242 in FIG. 1 or 3) extending from the folding area and disposed on the second housing, and a second planar area (e.g., the second planar area PA2 in FIGS. 4 to 6) extending from the flexible area, as a portion of the flexible glass, and in the folded state, the second display area may be disposed to at least partially face the first display area.

According to an embodiment, the electronic device may further include a compensating material (e.g., the compensating material 15 in FIG. 10) filled in the plurality of first recesses or the plurality of first holes, and the compensating material may be configured to compensate for a refractive index deviation of transmitted light at least in the flexible area.

According to an embodiment, the compensating material may be further disposed on at least one surface of the flexible glass.

It is to be understood that “holes,” specifically with respect to “the plurality of first holes” and “the plurality of second holes” as recited throughout the claims, should be interpreted as referring to holes, recesses, grooves, or any combination thereof.

According to an embodiment of the disclosure, as a flexible glass may include a plurality of grooves or a plurality of holes formed in a folded or rolled portion, stress caused by deformation into a curved shape may be mitigated. For example, for a flexible display or an electronic device including the same, an environment allowing for flexible deformation of the display or the electronic device may be created. According to an embodiment, with no grooves or holes formed in a portion where relatively low stress is generated during deformation of the flexible glass, the strength of the flexible glass may be ensured. For example, the flexible glass may be deformed smoothly while stably protecting a display panel in the portion where relatively low stress is generated.

The above-described embodiments are merely specific examples to describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

What is claimed is:

1. A flexible glass comprising:
a flexible area including a first side edge and a second side edge, and a lattice pattern area provided between the first side edge and the second side edge, the flexible area configured to be movable between a planar shape and a curved shape with respect to at least one folding axis extending along a first direction; and
a planar area provided on at least one side of the flexible area,
wherein the lattice pattern area including a plurality of first holes filled with a material for compensating a refractive index deviation of transmitted light in the flexible area,
wherein a first width of the lattice pattern area corresponding to at least one of the first side edge or the second side edge of the flexible area intersecting the at least one folding axis is greater than a second width of the lattice pattern area at a center between the first side edge and the second side edge of the flexible area.

2. The flexible glass of claim 1, wherein the first width of the lattice pattern area is at least 1.2 times the second width of the lattice pattern area.

3. The flexible glass of claim 1, wherein an edge of the lattice pattern area comprises at least one of a straight section or a curved section.

4. The flexible glass of claim 1, wherein a width of the plurality of first holes along a second direction intersecting the first direction increases based on a distance to the at least one of the first side edge or the second side edge.

5. The flexible glass of claim 1, wherein a spacing between two adjacent first holes among the plurality of first holes decreases based on a distance to the at least one of the first side edge or the second side edge.

6. The flexible glass of claim 1, wherein the compensating material is further provided on at least one surface of the flexible glass.

7. The flexible glass of claim 1, further comprising:
a glass layer provided from the flexible area to the planar area; and
a coating layer provided on at least one surface of the glass layer.

8. The flexible glass of claim 7, wherein the plurality of first holes are provided in the coating layer.

9. The flexible glass of claim 7, wherein the plurality of first holes are provided in the coating layer, and
wherein the glass layer comprises a plurality of second holes corresponding to the plurality of first holes.

10. The flexible glass of claim 9, further comprising a compensating material provided in at least some of the plurality of second holes,
wherein the compensating material is configured to compensate for a refractive index deviation of transmitted light in the flexible area.

11. The flexible glass of claim 1, wherein the planar area is provided on both sides of the flexible area, respectively, and
wherein as the flexible area is moved, the planar areas are configured to:
be disposed side by side, each on one side of the other, with the flexible area disposed therebetween, or
be disposed to at least partially face each other.

12. The flexible glass of claim 1, wherein the flexible area is provided side by side on one side of the planar area and configured to be moved to a position in which the flexible area at least partially faces the planar area at a specified spacing.

13. An electronic device comprising:
a first housing;
a second housing coupled to the first housing and configured to move with respect to the first housing; and
a flexible display comprising a first display area provided on the first housing, and a folding area extending from the first display area and configured to be movable into a planar shape and a curved shape according to movement of the second housing,
wherein the flexible display comprises the flexible glass of claim 1, and
wherein the flexible area of the flexible glass is provided in the folding area.

14. The electronic device of claim 13, further comprising a hinge providing the at least one folding axis, corresponding to the folding area, and pivotably connecting the first housing and the second housing to each other,
wherein the second housing is configured to move with respect to the at least one folding axis between a folded state in which the second housing faces the first housing and a flat state in which the second housing moves from the folded state by a specified angle.

15. The electronic device of claim 14, wherein the flexible display further comprises a second display area extending from the folding area and provided on the second housing, and
wherein in the folded state, the second display area is at least partially faces the first display area.
